(19) United States
(12) Patent Application Publication
(10) Pub. No.: US 2021/0005711 A1
(43) Pub. Date: Jan. 7, 2021

(54) VERTICAL POWER TRANSISTOR HAVING HETEROJUNCTIONS

(71) Applicant: Robert Bosch GmbH, Stuttgart (DE)

(72) Inventors: Alberto Martinez-Limia, Tuebingen (DE); Alfred Goerlach, Kusterdingen (DE); Holger Bartolf, Ofterdingen (DE); Stephan Schwaiger, Nehren (DE); Wolfgang Feiler, Reutlingen (DE)

(21) Appl. No.: 16/767,978

(22) PCT Filed: Nov. 19, 2018
(86) PCT No.: PCT/EP2018/081762

§ 371 Date: Jun. 17, 2020

(30) Foreign Application Priority Data
Nov. 23, 2017 (DE) 10 2017 220 913.5

(51) Int. Cl. H01L 29/06; H01L 29/16; H01L 29/78

(52) U.S. Cl. CPC H01L 29/0619; H01L 29/7802; H01L 29/1608

(57) ABSTRACT

A vertical power transistor, including a semiconductor substrate, on which at least one first layer and one second layer are situated, the second layer being situated on the first layer, and the first layer including a first semiconductor material; and a plurality of trenches, which extend from an upper side of the second layer into the first layer. The first layer has a first doping, and each trench has a first region, which extends from the respective trench bottom to a first level. Each first region is filled with a second semiconductor material, which has a second doping. The first semiconductor material and the second semiconductor material are different. Each first region is connected electrically to the second layer. The second doping is higher than the first doping. Heterojunctions, which behave as unipolar, rectifying junctions, form between the first layer and each first region.

### FIELD

The present invention relates to a vertical power transistor having a plurality of trenches; heterojunctions forming between the trenches and a first layer, and these heterojunctions behaving as unipolar, rectifying junctions.

### BACKGROUND INFORMATION

In vertical power transistors, the shielding of the gate oxide from high field intensities is problematic during blocking operation of the power transistor. In addition, it is difficult to limit the short-circuit current.

From the related art, different options are used for shielding the gate oxide in such a manner, that the intended service life of the component is maintained. One option is to introduce or bury p-doped regions in an epitaxial layer below the trench pattern of the power transistor. These p-doped regions are electrically connected to the source region of the power transistor. Their position underneath the MOS control head allows them to shield the MOS control head from high field intensities and contribute considerably towards limiting the short-circuit current. They also ensure that the maximum electrical field intensities in the blocking state of the component are localized deep in the semiconductor. This reduces the field intensities at the gate oxide considerably, which means that the service life of the component is significantly improved. In addition, the field intensities in the channel region are reduced by the deep, buried regions, so that short-channel effects, such as drain-induced barrier lowering, are prevented.

A disadvantage of this is that an additional epitaxial layer is required for producing the buried p-type regions. This is associated with high costs and further operational risks, as well as a high degree of operational complexity. The reason for this is that the MOS control head must be aligned precisely with the buried layers already produced. This is problematic, since the alignment marks of the first epitaxial layer, which are intended for the buried, p-doped regions produced at a later time, are rendered unusable by the additional epitaxial layer.

Another option is to produce deeply-extending p⁺ regions via implantation to the side of the MOS control head. In this context, the implantation of these regions is deeper than the MOS control head, so that the MOS control head is shielded from high field intensities. Consequently, the field intensities at the gate oxide are reduced considerably. This improves the service life of the component significantly. In addition, this reduces the field intensity in the channel region, so that short-channel effects are prevented.

In this connection, it is disadvantageous that high energies and, consequently, high implant masks must be used for the deep implantations, which means that high costs are generated and, due to the lateral dispersion of the implanted ions and the relatively wide patterns, the cell width of the transistor is very large on the basis of the level of the implantation masks. The RDS(on) is increased by the large cell width.

An object of the present invention is to improve the performance of a vertical power transistor.

### SUMMARY

In accordance with an example embodiment of the present invention, a vertical power transistor includes a semiconductor substrate, on which at least one first layer and one second layer are situated. The second layer is situated on the first layer, and the first layer includes a first semiconductor material. The vertical power transistor has a plurality of trenches, which extend from an upper side of the second layer into the first layer, so that the bottom of each trench is surrounded by the first layer. According to the present invention, the first layer has a first doping. Each trench has a first region, which extends from the respective trench bottom to a first level. Each first region is filled with a second semiconductor material, which has a second doping. The first semiconductor material and the second semiconductor material are different. This means that they have a different type of doping and a different doping. Each first region is connected electrically to the second layer. The second doping is higher than the first doping, which means that heterojunctions, which behave as unipolar, rectifying junctions, form between the first layer and each first region. The term unipolar junction includes Schottky junctions, heterojunctions, isotypic heterojunctions, or anisotypic heterojunctions. In this context, a classic Schottky junction is understood as a metal-semiconductor junction. In the case of a heterojunction, two different semiconductor materials are in contact. An isotypic heterojunction is understood to be a junction between two identical semiconductor materials, in which the same dopant atoms are used. An anisotypic heterojunction is understood as a junction between two identical semiconductor materials, in which different dopant atoms are used. In the unipolar junctions, only the majority charge carriers contribute to the charge-carrier current. The heterojunctions are rectifying; that is, depending on the polarity of the applied voltage, current flows through the junction, or it cuts off, since the second semiconductor material is highly doped. In other words, an energy barrier to the first layer forms. This energy barrier is a function of the doping levels of the first layer and the second layer. The absolute value of the energy barrier determines the forward voltage of the unipolar body diode of the component. A fundamental advantage of the heterojunctions over the classic Schottky junction is the absence of the image charge, that is, the image-force lowering. Therefore, the heterojunction does not exhibit a reduction in the energy barrier in response to an applied field. The advantage is that the leakage currents also remain independent of the blocking voltage in response to a high blocking voltage and, consequently, high field intensities in the vicinity of the heterojunction, since the barrier is not lowered by the absence of the image charge. In addition, the vertical power transistor has small, static losses due to the low forward voltage of the body diode during operation of the same. Two further technological advantages are derived from the unipolar nature of the body diode. Firstly, the switching-on and switching-off losses of a unipolar body diode are significantly less than those of the bipolar diode used in the related art. Secondly, bipolar operation may result in recombination of electrons and holes in the drift zone of the semiconductor. In particular, in WBG semiconductors, the so-called wide-bandgap semiconductors, this recombination energy is significantly higher than in a classic silicon semiconductor material. Thus, in the case of WBG semiconductors, bipolar operation may cause damage to the semiconductor crystal and, consequently, jeopardize the long-term stability of the component. For the material SiC, the electron-hole recombination at so-called basal plane dislocations may lead to degradation of the semiconductor crystal, that is, so-called bipolar degradation. Consequently, the unipolar diode has the advantage that it does not have any bipolar degradation. The unipolar diode has a low forward voltage and a low reverse recovery.

Therefore, the heterojunction has three outstanding characteristics, the shielding of the power-transistor head from high field intensities in the blocking case, the pinching-off of the conduction path in the case of a short circuit, and the unipolar, degradation-free, body-diode functionality during reverse operation of the power transistor.

In one further refinement of the present invention, a second region is situated on the first region. The second region is at least partially filled in with a metal. In this context, the metal is situated on side walls of the second region.

In this connection, it is advantageous that via the choice of the metal, the Schottky barrier may be selected to be very low. In this manner, the forward voltage at the junction of the second region and the first layer may be selected to be markedly below the forward voltage at the junction of the first region and the first layer. The second region is effectively shielded from high electric fields, which means that the barrier reduction of the Schottky barrier is negligibly small.

In one further refinement of the present invention, the first semiconductor material has a greater band gap than the second semiconductor material. In this connection, the advantage is that the blocking-state current is low.

In one further refinement of the present invention, the first doping has a doping concentration less than 10\hat{ }16 cm\hat{ }3.

In one further refinement of the present invention, the second doping has a doping concentration of at least 10\hat{ }15 cm\hat{ }−3.

In this connection, an advantage is that through the selection of the doping ratios and semiconductor materials, a low forward voltage of the unipolar diode may be generated.

In one further refinement of the present invention, the first doping is n-type doping, and the second doping is n-type doping or p-type doping.

In one further refinement of the present invention, the second semiconductor material includes polysilicon, Si or 3C—SiC.

In one further refinement of the present invention, the first semiconductor material includes 4H—SiC.

Further advantages are derived from the following description of exemplary embodiments, and the figures.

### BRIEF DESCRIPTION OF THE DRAWINGS

The present invention is explained below in light of preferred specific embodiments and figures.

FIG. 1 shows a vertical power transistor having heterojunctions, which behave electrically as unipolar, rectifying junctions in accordance with an example embodiment of the present invention.

FIG. 2 shows a further vertical power transistor having heterojunctions, which behave electrically as unipolar, rectifying junctions in accordance with an example embodiment of the present invention.

FIG. 3 shows a third quadrant of a current-voltage graph of the vertical transistor, the body diode being operated with a closed MOS channel in accordance with an example embodiment of the present invention.

FIG. 4 shows the band diagram of a heterojunction between the semiconductor materials n⁺ 3C—SiC and n⁻ 4H—SiC in accordance with an example embodiment of the present invention.

FIG. 5 shows a further vertical power transistor having heterojunctions, which are situated laterally next to the power transistor head in accordance with an example embodiment of the present invention.

FIG. 6 shows a further vertical power transistor having heterojunctions, which are situated both laterally next to the power transistor head and underneath the power transistor head in accordance with an example embodiment of the present invention.

### DETAILED DESCRIPTION OF EXAMPLE EMBODIMENTS

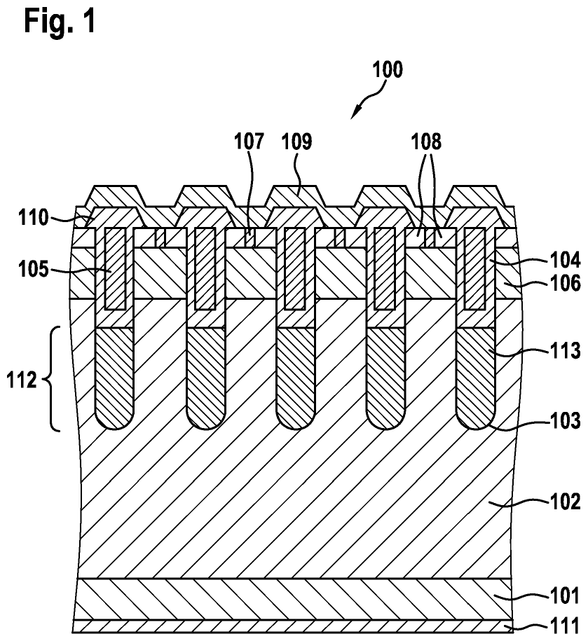

FIG. 1 shows a vertical power transistor 100 having heterojunctions, which behave as unipolar, rectifying junctions; Vertical power transistor 100 includes a semiconductor substrate 101, on which at least one first layer 102 and one second layer 108 are situated. First layer 102 includes a first semiconductor material, e.g., 4H—SiC, and has a first doping. The first doping includes a low doping concentration of n⁻ charge carriers. The doping concentration is usually less than 10\hat{ }16 cm\hat{ }−3. In this connection, first layer 102 represents an epitaxial layer, and second layer 108 represents the source region. A further layer 106, which represents the channel region, is situated between first layer 102 and second layer 108. The channel region is implanted or grown epitaxially. For example, the source region is highly n-doped, and the channel region is p-doped. Vertical power transistor 100 includes a plurality of trenches 103. Trenches 103 each include a trench bottom and side walls and extend from an upper side of second layer 108 into first layer 102. In other words, the bottoms of the trenches are surrounded by first layer 102. In this context, the trenches may extend substantially perpendicularly from the upper side of second layer 108 into first layer 102. Alternatively, they may have a non-right angle to the upper side of second layer 108 or may only start perpendicularly and then gradually change into a V-pattern. Trenches 103 have a trench depth between 0.5 μm and 10 μm. The spacing of individual trenches 103 is essentially equidistant and lies between 0.5 μm and 10 μm. Trenches 103 have a width of up to 5 μm. Each trench has a first region 112, which extends from the respective trench bottom to a first level. First regions 112 are filled with a second semiconductor material 113; second semiconductor material 113 having a second doping. The second semiconductor material is, for example, polysilicon or 3C—SiC. The second doping includes a high doping concentration of n-type or p-type charge carriers. The doping concentration is at least 10\hat{ }15 cm\hat{ }−3. In other words, second semiconductor material 113, which fills up first region 112, is highly doped, and the first semiconductor material is lowly doped. In addition, vertical power transistor 100 includes a gate dielectric 104, which insulates the power transistor head from second region 108. Gate dielectric 104 is made of, e.g., SiO₂. Furthermore, vertical power transistor 100 includes a gate electrode 105, p⁺-doped regions 107, an insulating layer 110 and a metallic layer 109. A metallic drain layer 111 is situated on a back side of semiconductor substrate 101. Gate electrode 105 includes, for example, doped polysilicon. The first level includes between ten and ninety percent of the trench depth. The first level is the same right down to the manufacturing tolerances in the individual trenches 103. First region 112 is connected electrically to second layer 108, pt-doped regions 107 and metallic layer 109, for example, with the aid of an ohmic contact.

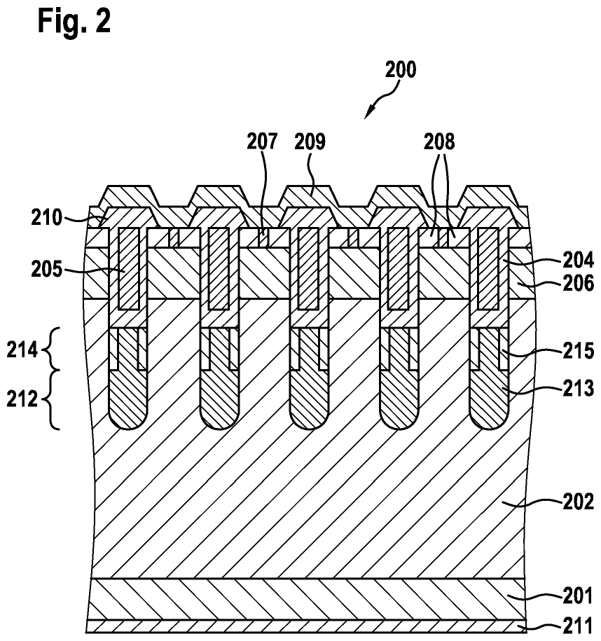

FIG. 2 shows a further, vertical power transistor 200 having heterojunctions, which behave as unipolar, rectifying junctions. Reference numerals from FIG. 2, which have the same trailing digits as the reference numerals from FIG. 1, denote the same features as in FIG. 1. In comparison to vertical power transistor 100 from FIG. 1, further vertical power transistor 200 additionally includes a second region 214, which is situated on first region 212. That is, second region 214 is situated between first region 212 and gate oxide 204, in trenches 213.

Second region 214 is at least partially filled in with a metal. In one exemplary embodiment, the metal is situated on the side walls of second region 214. In another exemplary embodiment, second region 214 is filled with metal. The metal includes, for example, Ni or Ti.

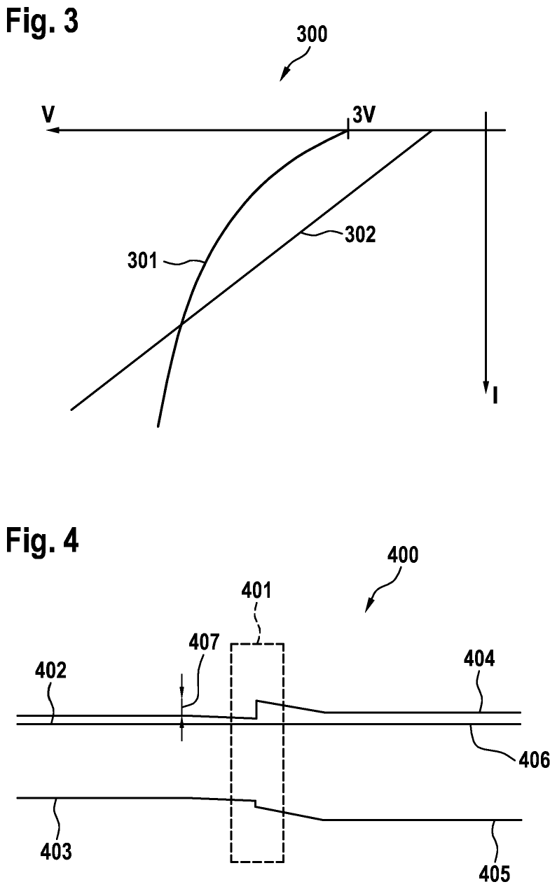

FIG. 3 shows the third quadrant of the current-voltage graph 300 of a vertical power transistor. Curve 301 shows the current-voltage characteristic of a vertical power transistor having a bipolar body diode, from the related art. Curve 302 shows the current-voltage characteristic of a vertical power transistor having a unipolar heterojunction. Curve 302 is distinguished in that in reverse operation, the vertical power transistor has a considerably lower forward voltage than the vertical power transistor from curve 301.

FIG. 4 shows an example of a band diagram 400 of a heterojunction 401 between the semiconductor materials n⁺ 3C—SiC and n⁻ 4H—SiC. On the basis of the different crystal forms, these two materials may be regarded as different semiconductor materials, which means that the transition from 3C—SiC to 4H—SiC may be considered a heterojunction. The present case concerns an isotypic heterojunction. Band diagram 400 includes valence band 403 and conduction band 402 of semiconductor material n⁺ 3C—SiC, valence band 405 and conduction band 404 of semiconductor material n⁻ 4H—SiC, as well as Fermi level 406. An energy barrier 407 to the semiconductor crystal, that is, in this case, n⁻ 4H—SiC, is formed at heterojunction 401. This energy barrier 407 does not have any barrier lowering.

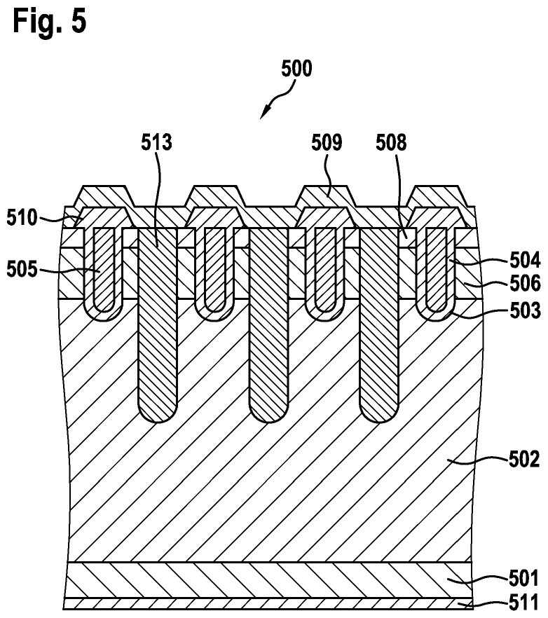

FIG. 5 shows a further vertical power transistor 500 having heterojunctions, which are situated laterally next to the power transistor head. In this context, the power transistor head includes gate oxide 504 and gate electrode 505. Reference numerals from FIG. 5, which have the same trailing digits as the reference numerals from FIG. 1, denote the same features as in FIG. 1. The distance between the trenches of the power transistor heads and the trenches, which have the heterojunctions, is between 0.1 μm and 10 μm.

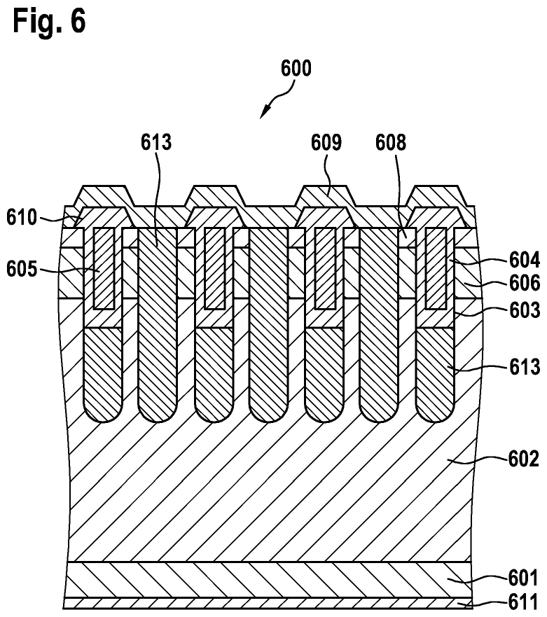

FIG. 6 shows a further vertical power transistor 600 having heterojunctions, which are situated both laterally next to the power transistor head and underneath the power transistor head. Thus, the vertical power transistor includes two trench types, the one trench type for the power transistor head, which has further heterojunctions underneath the MOS control head, and the other trench type for the heterojunctions. In this case, the depth of the individual trench types may vary. The trenches may have a depth between 0.5 μm and 20 μm. Reference numerals from FIG. 6, which have the same trailing digits as the reference numerals from FIG. 1, denote the same features as in FIG. 1.

The vertical power transistor having heterojunctions, which behave as unipolar, rectifying junctions, may be used in vehicle inverters, photovoltaic inverters, train drive units or high-voltage, direct-current transmission systems.

1-8. (canceled)

9. A vertical power transistor, comprising:
a semiconductor substrate, on which at least one first layer and one second layer are situated, the second layer being situated on the first layer, and the first layer including a first semiconductor material; and
a plurality of trenches which extend from an upper side of the second layer into the first layer, so that a respective trench bottom of each of the trenches is surrounded by the first layer;
wherein:
the first layer has a first doping, and each of the trenches has a first region which extends from the respective trench bottom to a first level, each of the first regions being filled with a second semiconductor material, which has a second doping;
the first semiconductor material and the second semiconductor material are different from one another;
each of the first regions is connected electrically to the second layer; and
the second doping being higher than the first doping, so that heterojunctions, which behave as unipolar, rectifying junctions, form between the first layer and each of the first regions.

10. The vertical power transistor as recited in claim 9, wherein a second region is situated on each of the first regions, the second regions being filled at least partially with a metal, and the metal being situated on side walls of the second regions.

11. The vertical power transistor as recited in claim 9, wherein the first semiconductor material has a greater band gap than the second semiconductor material.

12. The vertical power transistor as recited in claim 9, wherein the first doping has a doping concentration less than 10\hat{ }16 cm\hat{ }−3.

13. The vertical power transistor as recited in claim 9, wherein the second doping has a doping concentration of at least 10\hat{ }15 cm\hat{ }−3.

14. The vertical power transistor as recited in claim 9, wherein the first doping is n-type doping, and the second doping is n-type doping or p-type doping.

15. The vertical power transistor as recited in claim 9, wherein the second semiconductor material includes Si or 3C—SiC.

16. The vertical power transistor as recited in claim 9, wherein the first semiconductor material includes 4H—SiC.
